(19) United States
(12) Patent Application Publication
(10) Pub. No.: US 2006/0144822 A1
(43) Pub. Date: Jul. 6, 2006

(54) Apparatus and method for wet-etching

(75) Inventors: Sheng-Chou Gau, Miao-Li (TW); Jung-Lung Huang, Miao-Li (TW); Chen-Hsien Ou, Miao-Li (TW); Li-Feng Chiu, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/317,858

(22) Filed: Dec. 23, 2005

(30) Foreign Application Priority Data
Dec. 30, 2004 (CN) 200410091969.0

(51) Int. Cl. B44C 1/22; C23F 1/00; H01L 21/302; H01L 21/306

(52) U.S. Cl. 216/83; 438/745; 156/345.11; 156/345.17

(57) ABSTRACT

A wet-etching apparatus (20) includes a first etching chamber (213), a second etching chamber (215), and a cleaning chamber (214) located between the first and second etching chambers. The wet-etching apparatus includes the cleaning chamber disposed between the first and second etching chambers. After being etched in the first etching chamber and before being conveyed to the second etching chamber, a glass substrate is cleaned, so that the residue thereon is removed. Because no resultant blocks the wet-etching reaction, the glass substrate is etched uniformly. Thus, the quality and the yield of the wet-etching process are improved.

### FIELD OF THE INVENTION

The present invention relates to an apparatus and a method for wet-etching.

### BACKGROUND

Because a wet-etching process has low cost, a high yield, and high reliability, it has been widely used in the process of etching glass substrates used for thin film transistor liquid crystal displays (TFT-LCDs).

Referring to FIG. 4, a conventional wet-etching apparatus 10 includes a maintenance area 110, a waiting chamber 111, a buffering chamber 112, a first etching chamber 113, a second etching chamber 114, a third etching chamber 115, a wet-conveying chamber 116, a rinsing chamber 117, a drying chamber 118, and a dry-conveying chamber 119. The waiting chamber 111, the buffering chamber 112, the first etching chamber 113, the second etching chamber 114, the third etching chamber 115, the wet-conveying chamber 116, the rinsing chamber 117, the drying chamber 118, and the dry-conveying chamber 119 are connected end to end, thereby forming a rectangular arrangement. The maintenance area 110 is located in a middle of the rectangular arrangement.

Operation of the wet-etching apparatus 10 is as follows. First, a glass substrate is conveyed to the wet-etching apparatus 10, and is held in the waiting chamber 111. The glass substrate is first conveyed to the first etching chamber 113 via the buffering chamber 112. The glass substrate is then conveyed through the first, second and third etching chambers 113, 114, 115, in which successive processes of etching take place. In the first etching chamber 113 in particular, the etching process generates residue that is deposited on a surface of the glass substrate. After the three etching processes, the glass substrate is conveyed to the wet-conveying chamber 116. In the wet-conveying chamber 116, deionized water is used to clean the glass substrate under high-pressure airflow. The glass substrate is then sequentially conveyed through the rinsing chamber 117, the drying chamber 118, and the dry-conveying chamber 119. In the rinsing chamber 117, a high-pressure water column is used to scrape the residue from the surface of the glass substrate, and subsequently a high-density spray is used to thoroughly rinse the surface. After being dried in the drying chamber 118, the glass substrate is conveyed to the waiting chamber 111 via the dry-conveying chamber 119. Thereafter, the substrate is conveyed to a next processing apparatus (not shown).

The maintenance area 110 is essentially enclosed, and includes chemical pipelines and gas pipelines therein. Maintenance personnel can enter the maintenance area 110 via an entryway under the buffering chamber 112, in order to maintain the pipelines.

In general, the residue at edges of the surface of the glass substrate is relatively easy to remove, while the residue at a middle of the surface is difficult to remove. The residue deposited on the surface of the glass substrate blocks the wet-etching of the glass substrate. Therefore an etching speed at the edges of the surface of the glass substrate is higher than an etching speed at the middle of the surface. In the wet-etching apparatus 10, the glass substrate is conveyed continuously through the first etching chamber 113, the second etching chamber 114, and the third etching chamber 115. The wet-etching is isotropic etching. That is, the glass substrate is not only horizontally etched but also vertically etched. After being continuously etched in the three etching chambers 113, 114, 115, the edges of the surface of the glass substrate tend to be heavily horizontally etched, resulting in an undercut effect. Thus the overall quality of wet-etched glass substrates is degraded, and the yield of satisfactory glass substrates is reduced.

It is desired to provide a wet-etching apparatus that overcomes the above-described problems.

### SUMMARY

A wet-etching apparatus is provided. The wet-etching apparatus includes a first etching chamber, a second etching chamber, and a cleaning chamber located between the first and second etching chambers. Residue produced in the first etching chamber is removed in the cleaning chamber.

Other advantages and novel features of various embodiments will become more apparent from the following detailed description when taken in conjunction with the accompanying drawings.

### BRIEF DESCRIPTION OF THE DRAWINGS

FIG. 1 is a schematic, isometric view of a wet-etching apparatus according to a first embodiment of the present invention.

FIG. 2 is a schematic, isometric view of a wet-etching apparatus according to a second embodiment of the present invention.

FIG. 3 is a flow chart of a wet-etching method according to another embodiment of the present invention.

FIG. 4 is a schematic, isometric view of a conventional wet-etching apparatus.

### DETAILED DESCRIPTION OF PREFERRED EMBODIMENTS

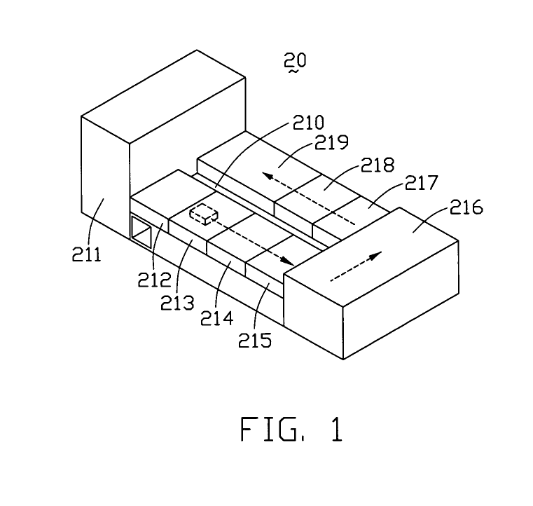

Referring to FIG. 1, a wet-etching apparatus 20 according to a first embodiment of the present invention includes a maintenance area 210, a waiting chamber 211, a buffering chamber 212, a first etching chamber 213, a cleaning chamber 214, a second chamber 215, a wet-conveying chamber 216, a rinsing chamber 217, a drying chamber 218, and a dry-conveying chamber 219. The waiting chamber 211, the buffering chamber 212, the first etching chamber 213, the cleaning chamber 214, the second etching chamber 215, the wet-conveying chamber 216, the rinsing chamber 217, the drying chamber 118, and the dry-conveying chamber 219 are connected end to end, thereby forming a rectangular arrangement. The maintenance area 210 is located in a middle of the rectangular arrangement.

Operation of the wet-etching apparatus 20 is as follows. First, a glass substrate is conveyed to the wet-etching apparatus 20, and is held in the waiting chamber 211. The glass substrate is first conveyed to the buffering chamber 112. The glass substrate is then sequentially conveyed through the first etching chamber 213, the cleaning chamber 214, and the second etching chamber 215. In the first etching chamber 213, the etching process generates residue that is deposited on a surface of the glass substrate. In the cleaning chamber 214, a high-pressure water column is used to scrape the residue from the surface of the glass substrate. The surface of the glass substrate, including edges and a middle thereof, is thus free from residue once the glass substrate enters the second etching chamber 215. Accordingly, the glass substrate can be etched uniformly in the second etching chamber 215. Thus, the quality and the yield of finished glass substrates produced by the wet-etching process are improved.

After being etched in the second etching chamber 215, the glass substrate is conveyed to the wet-conveying chamber 216. In the wet-conveying chamber 216, deionized water is used to wash the glass substrate under high-pressure airflow. The glass substrate is then sequentially conveyed through the rinsing chamber 217, the drying chamber 218, and the dry-conveying chamber 219. In the rinsing chamber 217, a high-pressure water column is used to scrape residue from the surface of the glass substrate, and subsequently a high-density spray is used to thoroughly rinse the surface. After being dried in the drying chamber 218, the glass substrate is conveyed to the waiting chamber 211 via the dry-conveying chamber 219. Thereafter, the substrate is conveyed to a next processing apparatus (not shown).

The wet-etching apparatus 20 includes the cleaning chamber 214 disposed between the first and second etching chambers 213, 215. After being etched in the first etching chamber 213 and before being conveyed to the second etching chamber 215, the surface of the glass substrate is cleaned so that the residue thereon is removed. Because there is no residue blocking the wet-etching process in the second etching chamber 215, the glass substrate is etched uniformly. Thus, the quality and the yield of finished glass substrates produced by the wet-etching process are improved.

Referring to FIG. 2, a wet-etching apparatus 30 according to a second embodiment of the present invention includes a waiting chamber 311, a dry-conveying chamber 319, a drying chamber 318, a rinsing chamber 317, a second etching chamber 316, a cleaning chamber 315, a first etching chamber 314, a lifter 313, and a dry conveyor belt 312 connected end to end. The conveying line 312 is above all of the dry-conveying chamber 319, the drying chamber 318, the rinsing chamber 317, the second etching chamber 316, the cleaning chamber 315, and the first etching chamber 314. The dry conveyor belt 312 is connected with the first etching chamber 314 via the lifter 313.

In operation of the wet-etching apparatus 30, a glass substrate in the waiting chamber 311 is conveyed to the lifter 313 continuously via the dry conveyor belt 312. The glass substrate is conveyed down and subsequently through the first etching chamber 314, the cleaning chamber 315, the second etching chamber 316, the rinsing chamber 317, the drying chamber 318 and the dry-conveying chamber 319. Finally, the glass substrate is conveyed to the waiting chamber 311. Thereafter, the substrate is conveyed to a next processing apparatus (not shown).

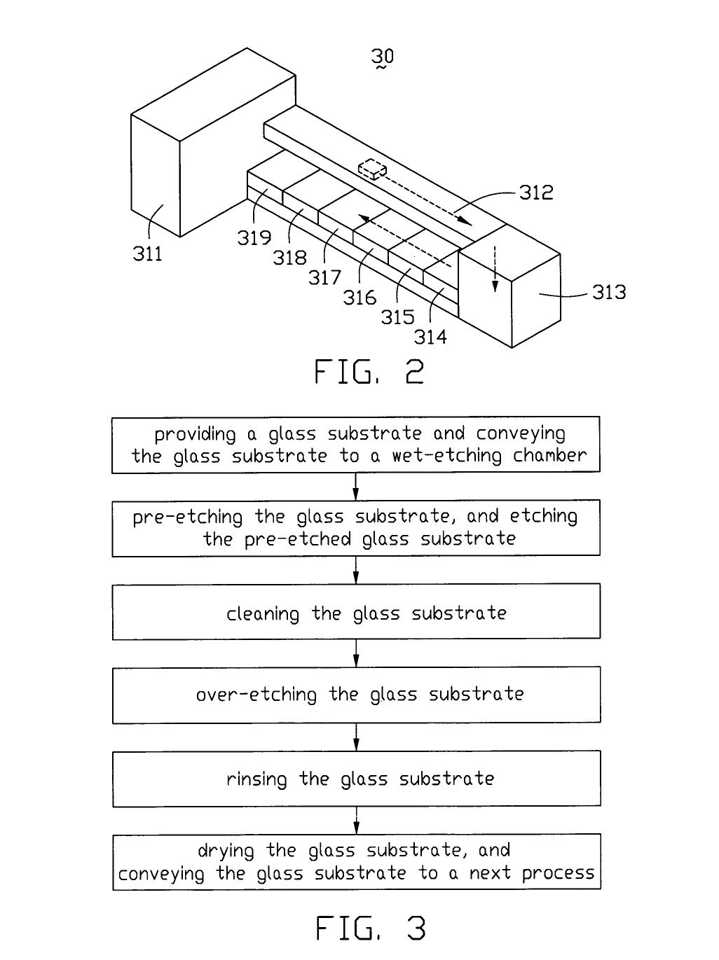

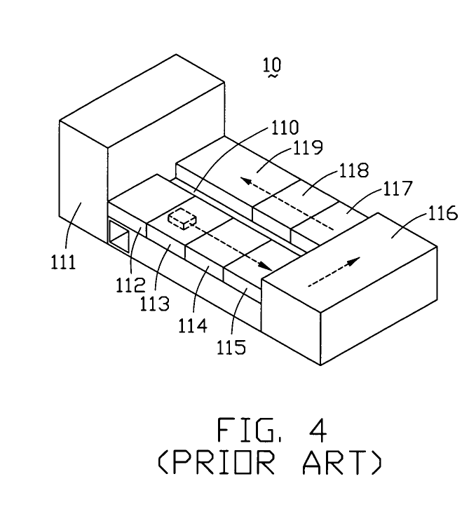

FIG. 3 is a flow chart of a wet-etching process according to another embodiment of the present invention. The wet-etching process includes the following steps: providing a glass substrate, and conveying the glass substrate to a wet-etching chamber; pre-etching the glass substrate, and then etching the pre-etched glass substrate; cleaning the glass substrate using high-pressure water column in order to remove residue; over-etching the etched glass substrate; rinsing the glass substrate using a high-pressure water column and a high-density spray; and drying the glass substrate, and then conveying the glass substrate to a next process.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. A wet-etching apparatus, comprising:
a first etching chamber;
a second etching chamber; and
a cleaning chamber located between the first and second etching chambers;
wherein residue produced in the first etching chamber is removed in the cleaning chamber.

2. The wet-etching apparatus as claimed in claim 1, further comprising a waiting chamber for holding substrates to be etched.

3. The wet-etching apparatus as claimed in claim 2, further comprising a buffering chamber for conveying substrates from the waiting chamber to the first etching chamber.

4. The wet-etching apparatus as claimed in claim 3, further comprising a rinsing chamber for rinsing substrates that have been processed in the first and second etching chambers.

5. The wet-etching apparatus as claimed in claim 4, further comprising a dry-conveying chamber for conveying the substrates from the rinsing chamber to the waiting chamber.

6. The wet-etching apparatus as claimed in claim 5, further comprising a wet-conveying chamber disposed between the second etching chamber and the rinsing chamber.

7. A wet-etching method, comprising:
wet-etching a substrate a first time;
cleaning the substrate to remove residue from the substrate, the residue being produced in the first etching chamber; and
wet-etching the substrate a second time.

8. The wet-etching process as claimed in claim 7, wherein the first wet-etching comprises pre-etching and etching.

9. The wet-etching process as claimed in claim 7, wherein the second wet-etching is over-etching.

10. The wet-etching process as claimed in claim 7, further comprising rinsing the substrate after etching the substrate a second time.

11. The wet-etching process as claimed in claim 10, further comprising drying the substrate after rinsing the substrate.

12. The wet-etching process as claimed in claim 7, wherein a high-pressure water column is used to clean the substrate.

13. The wet-etching process as claimed in claim 7, wherein a high-pressure water column and a high-density spray are used to rinse the substrate.
